(19) United States
(12) Patent Application Publication
(10) Pub. No.: US 2023/0382267 A1
(43) Pub. Date: Nov. 30, 2023

(54) METHOD AND APPARATUS FOR THE USER-DEPENDENT SELECTION OF A BATTERY OPERATED TECHNICAL DEVICE DEPENDING ON A USER USAGE PROFILE

(71) Applicant: Robert Bosch GmbH, Stuttgart (DE)

(72) Inventors: Christian Simonis, Leonberg (DE); Christoph Woll, Gerlingen (DE); Stefan Schindler, Bietigheim-Bissingen (DE)

(21) Appl. No.: 18/325,215

(22) Filed: May 30, 2023

(30) Foreign Application Priority Data
May 31, 2022 (DE) 10 2022 113 681.7

(51) Int. Cl. B60L 58/16; G01R 31/367; G01R 31/392

(52) U.S. Cl. CPC B60L 58/16; G01R 31/367; G01R 31/392

(57) ABSTRACT

A computer-implemented method for assigning a device type of a battery powered technical device having a device battery and belonging to a plurality of various device types to a user.

### BACKGROUND

The invention relates to an assignment situation in which a user is to be assigned to one of a plurality of various battery powered technical devices. In particular, a battery powered vehicle belonging to a pool of vehicles is to be assigned to a specific driver with a known driving behavior.

The supply of energy to electrical devices and machines operated independent of a network, e.g., electrically powerable motor vehicles, is normally performed by means of device batteries or vehicle batteries. The latter supply electrical energy used to operate the devices.

Device batteries degrade over their service life and according to their load or usage. Referred to as ageing, the result is a continuously decreasing maximum power or storage capacity. The ageing state corresponds to a measure used to indicate the ageing of energy storage means. Conventionally, a new device battery can have a 100% ageing state (regarding its capacity, SOH-C), which decreases more and more over the course of the battery service life. The degree of ageing of the device battery (temporal change in the ageing state) depends on an individual load on the device battery, i.e., in the case of vehicle batteries of motor vehicles, the usage behavior of a driver, external ambient conditions, and the type of vehicle battery.

In order to monitor device batteries belonging to a plurality of devices, operational parameter data is typically continuously recorded and transmitted as operational parameter profiles in block fashion to an in-device central unit. To evaluate the operational parameter data, in particular to determine ageing states in models based on differential equations, the operational parameter data is sampled at a comparatively high temporal resolution (sampling rates) of, e.g., between 1 and 100 Hz, and an ageing state is thereby determined using a chronological integration method.

In battery powered vehicles, the determination of the ageing state is performed at fixed intervals of time, e.g., once a week. Prediction of the ageing state can be performed depending on a known driving behavior of the driver.

### SUMMARY

Provided according to the invention are a method for associating a battery powered technical device having at least one device battery with a specific user having a usage behavior, as well as a corresponding apparatus.

Provided according to a first aspect is a method for assigning a device type of a battery powered technical device having a device battery and belonging to a plurality of various device types to a user, said method comprising the following steps:
providing a usage behavior of the user;
assigning a usage category to the user's usage behavior;
determining a predicted usage parameter profile of at least one usage parameter corresponding to the usage category, wherein the at least one usage parameter is indicative of a parameter indicative of an operational mode of the technical device exerting a load on the device battery;
simulating a predicted ageing state profile for the predicted usage parameter profile for a predetermined amount of time for each type of device of a plurality of device types in order to determine a predicted ageing state at a predetermined end of useful life period;
selecting a device type for the user depending on the predicted ageing state.

The ageing state of a device battery is usually not directly measured. Doing so would require a number of sensors inside the device battery, which would make the production of such a device battery cost-intensive, as well as complex, and would increase the space requirement. Moreover, measurement methods suitable for everyday use for direct determination of the ageing state in the energy stores are not yet available on the market.

The ageing state is currently determined in a battery control device provided near the battery and read during an inspection or maintenance of the device. The ageing conditions provided are determined during travel or after a charging operation under various conditions and depending on the algorithm used for determining the ageing state. The methods used can vary significantly in part so that comparability of ageing conditions read from the battery control devices is generally not possible across a plurality of technical devices. The inaccuracies can be up to 5%. The exact determination of the ageing state is important for the device user, since this can result in a remaining service life of the device battery and correspondingly the future potential use of the device.

In the case of device batteries, the ageing state (state of health, SOH) is the key parameter for indicating a remaining battery capacity or remaining battery charge. The ageing state represents a measure of the ageing of the device battery. In the case of a device battery or a battery module or a battery cell, the ageing state can be indicated as a capacity retention rate (SOH-C). The capacity retention rate (SOH-C) is indicated as the ratio between the measured instantaneous capacity and an initial capacity of the fully charged battery. This rate decreases with increasing ageing. Alternatively, the ageing state can be indicated as an increase in internal resistance (SOH-R) with respect to internal resistance at the start of the service life of the device battery. The relative change in the internal resistance SOH-R increases with increasing ageing of the battery.

In leased battery powered equipment, e.g., vehicles for lease, i.e., technical devices or vehicles intended for a different usage after a predetermined useful life period, it is however important to what extent the vehicle battery ages during the leasing period since the residual value of the device or vehicle is usually determined by the ageing state at the end of the useful life period. A leasing customer pays a fixed leasing rate, for the use which is tied to further boundary conditions, e.g., a maximum energy expenditure for a technical device or a mileage for a vehicle. However, the usage behavior of a user as a lessee can vary greatly from user to user, thereby placing varying loads on the vehicle battery.

Since the actual use of the device battery cannot be precisely determined by known diagnostic measurements, the usage behavior cannot be established in the form of a leasing condition. For the leasing provider, however, the content of the agreement it is as important how the expected residual value of the technical device at the end of the lease term is. In particular, one difficulty lies in determining a fair leasing rate for various device types having various operational characteristics and configurations as well as various battery types, since various device types having various device batteries age to different degrees, depending on the usage behavior, so they have varying residual values at the end of the useful life period. This is particularly true because various stress factors affect different types of batteries in devices of various types to varying degrees.

Users operating a battery powered device for a specific useful life period operate it with varying usage behavior, i.e., regarding operating cycles, charging cycles, and idle cycles, each of which is of varying duration and intensity of use. In battery powered devices, the type of use of the device can be determined by the ageing of the device battery over the course of the useful life period. In particular, in vehicles as examples of battery powered technical devices, the ageing state of the associated vehicle battery can be continuously monitored as a device battery, in particular by transmitting operational parameter profiles to a remote central unit that determines an ageing state of the device battery at regular intervals, e.g., weekly. As a result, a specific device can be classified according to user behavior via the ongoing ageing, depending on the extent to which the device battery of the relevant device is stressed by the usage mode by the user.

Since in particular the usage mode for various technical devices, i.e., for example vehicles of various types or various powertrains, can cause very different ageing processes in various device batteries, selecting the assignment of a user with a specific usage behavior with respect to a specific device, e.g., a specific leasing vehicle, can take place depending on which of the devices achieves the lowest possible ageing of the device battery.

It can be provided that the usage behavior of the user is continuously recorded based on at least one usage parameter and is in particular derived from historical profiles of at least one usage parameter, wherein the usage behavior is aggregated into usage characteristics, wherein the usage categories is determined by characteristics of the usage characteristics.

The usage characteristics can further include an average load during operation, a duration of operation relative to the calendar age, and a frequency of use, in particular in vehicles acting as technical devices, wherein the usage characteristics include a predicted annual travel path, a number and type of charging cycles, a temperature range, an average load range.

The above method is based on a user whose usage behavior has been characterized. The usage behavior of the technical device can be determined by the intensity of usage (average and/or maximum discharging current during operating periods), operating duration (ratio of accumulated operating period to calendar total age), charging behavior, and the like. The usage behavior of the technical device in the case of a vehicle can be determined based on a driving style, a travel distance, a travel path or a loading behavior, and the like. For example, the usage behaviors can be classified based on the ranges of annual travel performance, charging behavior, i.e., with what portion the driver charges the vehicle during a fast charging operation and during a normal charging operation, and what average charge state strokes are achieved during a charging operation, the driving style, i.e., amount of average acceleration during travel, and frequency of accelerations during the useful life period, and ambient conditions, i.e., within what temperature range the vehicle is moving.

A user's usage behavior can be detected during a user's previous usage and stored in a database accordingly. The usage parameter profiles of the user can be aggregated into usage characteristics, e.g., the intensity of usage, the overall service life, type of usage, e.g., frequency of load changes, charging behavior, and the like. The usage behavior can be classified into one of multiple usage categories. The usage categories represent ranges of aggregate usage characteristics, e.g., average load during operation, operating period with respect to calendar age, frequency of usage, and the like. In particular, for vehicles, these usage categories can include information about a traveled distance per unit of time, predicted annual mileage, number and type of charging cycles, a temperature range, a load range, and the like.

The usage category then enables modeling of an “artificial” predicted usage history from usage cycles that might correspond to the driver's usage behavior and result in a comparable load on the technical device that would be present when the user actually uses the technical device. For example, these usage cycles can comprise an operational cycle, a charging cycle, and a sleep cycle, and can indicate profile portions of usage parameter profiles, e.g., profiles of the climatic conditions during use (average ambient temperature profile), a speed profile in a vehicle, a charging current profile, and charging state increase during a charging operation, and the like. The predicted usage variable profile thus defines usage variable profiles over the entire useful life period, during which the technical device is intended to be associated with the user.

The predicted usage variable profiles can then be converted to predicted load variable profiles by means of a data based, mathematically based, or physically based operational model. The predicted load variable profiles represent profiles of one or more predicted operational variables for the device battery of the technical device in question, which profiles enable an ageing condition to be predicted. For example, the load variable profiles can indicate profiles of the battery current and the battery temperature. These profiles can be supplemented with a battery performance model using modeled profiles of the battery voltage and state of charge as further operational variables, if necessary. The predicted operational variable profiles for the device battery, which profiles can be modeled to a predicted age state using an ageing state model of the device battery used in the technical device, thus obtaining a predicted ageing state.

Furthermore, at least another one of the at least one operational variables can be determined by means of a battery performance model based on operational variable profiles previously predicted by means of the operational model, wherein the model parameters of the battery performance model can be adjusted with respect to the respective predicted ageing state for the simulation.

In the case of a vehicle as a technical device, a powertrain model can be provided as an operational model so that load variable profiles predicted based on the predicted usage variable profiles can be determined. For example, under a specific climatic ambient condition, e.g., a specific ambient temperature and at a predetermined speed profile, a corresponding battery current profile can be determined that would result for the specific vehicle. Properties of the electric drive motor from frictional resistances of the drivetrain and from battery properties, e.g., the battery voltage, are thereby included. These properties are vehicle-specific, so the predicted usage parameter profiles as a chronological series of one or more usage parameters for each vehicle type and each battery type results in various predicted load parameter profiles for the vehicle battery.

Ageing state models evaluating temporal operational parameter profiles are known from the prior art and can in particular consist of a differential equation system which uses a chronological integration method in order to determine the current ageing state at a specific time, depending on the operational parameter profile up to the specific point in time.

Ageing state models used to determine ageing states for electrical energy stores can be provided in the form of a hybrid ageing state model, i.e., a combination of a physical ageing model with a data-based model. In a hybrid model, a physical ageing state can be determined by means of a physical or electrochemical ageing model, and a correction value resulting from a data-based correction model can be applied to said ageing state, in particular by means of addition or multiplication.

The physical ageing model can be based on electrochemical model equations of a non-linear differential equation system characterizing electrochemical states continuously calculated in a chronological integration method based on the operational parameter profiles, wherein the internal states are used to determine the physical ageing state as SOH-C and/or as SOH-R. The calculations and predictions can typically be performed in the cloud, e.g., once a week or (alternatively or additionally) when a battery has just been replaced or is being recharged while in storage.

Furthermore, the correction model of the hybrid data-based ageing state model can be designed with a probabilistic or artificial intelligence-based probabilistic regression model, in particular a Gaussian process model, and can be trained to correct the ageing state obtained by the physical ageing model. For this purpose, a data-based correction model is then made of the ageing state in order to correct the SOH-C and/or at least one further model for correcting the SOH-R. Possible alternatives to the Gaussian process include further supervised learning methods, e.g., based on a random forest model, an AdaBoost model, a support vector machine, or a Bayesian neural network.

A predicted profile of the ageing state, which profile indicates the ageing state at the end of the leasing period or useful life period thus results for each usage category associated with a specific operational model of a specific device or device type. The difference in ageing state over the useful life period indicates the usage of the device battery when used by a user whose usage behavior corresponds to the specific category of use. Given differences between the implementation of the usage parameter profiles in the device and operational parameter profiles for the device battery used therein, which profiles are indicated by the operational model associated with the device, various usage patterns in various types of vehicles lead to various cyclic ageing processes.

Since the ageing state of device batteries indicates to a considerable extent the residual value or the potential use of the technical device, the association of a specific user, whose usage behavior is known, with a specific device is important when optimizing the residual value/potential use of a plurality of technical devices in a device pool.

According to the above method, a database is created for each of the devices of the equipment pool, including possible predicted usage parameter profiles for various usage categories for a predetermined useful life period as well as a change in the ageing state calculated over that respective useful life period. Periods with pronounced ageing behavior can be indicated by these cycles, so stress factors can be determined within the categorized ranges of the usage properties. These stress factors are characterized by one or more characteristic areas of the usage properties.

As a result, an individual change in ageing state can be determined regarding each of the usage categories for each device with respect to a predetermined useful life period.

The method can be performed in a conventional computer system for a user when a user's usage behavior is provided. This behavior can be derived from the collection of usages by the relevant user in the past, or it can be specified in any other way. One behavior can be selected from the possible usage categories according to the user behaviors provided. Each usage category is associated with a representative predicted usage parameter history, which can be indicative of usage for a predetermined period of time, e.g., one week. The predicted temporal usage parameter profile can indicate a temporal load profile which can be described, e.g., by representative speed and charging current profiles.

It can be provided that simulating the predicted ageing state profile for the predicted usage parameter profile comprises first predicting at least one operational parameter profile for the device battery by means of a predetermined useful life operational model for each type of device, then predicting the ageing state profile by means of an ageing state model, wherein the ageing state model is based on a differential equation system which determines the ageing state by means of a chronological integration method.

This predicted usage parameter profile is used for predicting the state of ageing in order to make a prediction of the change in the ageing state of the device battery for a predetermined period of use. To this end, the usage parameter profile is first converted to a predicted load parameter profile over the vehicle battery via an operational model of the technical device. In the case of a vehicle acting as a technical device, this conversion is based on vehicle features, e.g., a voltage level of the vehicle battery, the number of driven axles, or the design of the reduction gear train. This information results in a vehicle-specific association of the drive torque being provided with regard to the vehicle speed and the resulting required motor current profile, based on which the battery current profile essentially depends.

Using a battery performance model, the motor current profile, which corresponds essentially to the battery current profile, and a temperature profile resulting from the battery load and a forecasted profile of the ambient temperature can then be modeled using further operational variables of the device battery, e.g., the profiles of the battery voltage and the state of charge.

The battery current, the battery temperature, the battery voltage, and the state of charge, based on which an ageing state can be determined by means of the ageing state model, are then available as operational parameter profiles.

By predicating “artificial” usage parameter profiles up to the desired usage duration, a change in the ageing state from the start of the usage time period to the end of the usage time period can then be detected. Doing so enables a user usage category to be assigned for each of the relevant devices with respect to a change in ageing state.

According to one embodiment, selecting a device type for the user can be performed on a rule-based basis at the end of the predetermined useful life period, in particular so that a remaining potential use of the device battery is at a maximum.

In the ageing simulation, the battery performance model used can be successively adjusted with respect to the current ageing state in order to provide age-dependent modeling of the battery voltage and state of charge. Therefore, when a user is assigned to a specific technical device, the anticipated change in ageing state for a predetermined useful life period can be determined for all technical devices of the pool of equipment and can be made depending upon the respective associated change in ageing state. In particular, the ageing state can result in a residual value/potential use of the technical device, which is significantly influenced by the change in the ageing state of the device battery.

Advantageously, the method according to the invention finds use for electrically driven vehicles for a simulation of an operational strategy on power and thermal behavior in the closed control loop, wherein an overall vehicle model, a powertrain model, and/or a battery model is provided as an operational model in order to predict a state of an energy converter or electrochemical energy storage means of the electrically driven vehicle.

According to a further aspect, an apparatus is provided for performing the above method.

### BRIEF DESCRIPTION OF THE DRAWINGS

Embodiments are explained in more detail below with reference to the accompanying drawings. Shown are:

FIG. 1 a flow chart illustrating a method of associating a vehicle belonging to a plurality of vehicle types with a user having a predetermined usage profile;

FIG. 2 a chart of possible usage categories for various driver behaviors;

FIG. 3 a graph of the profiles of the ageing state of vehicle batteries of various vehicles over time;

FIG. 4 schematic illustration of a flowchart of an embodiment of a method according to the invention.

### DETAILED DESCRIPTION

In the following, the method according to the invention is described based on vehicles of a vehicle pool as an example of technical devices of various device types using vehicle batteries as device batteries. The method is performed in a data processing apparatus, in which the method described below is implemented as software and/or hardware. The example is representative of a plurality of stationary or mobile devices with off-grid power supplies, e.g., equipment, machine tools, domestic devices, Internet of Things (IoT) devices, and the like.

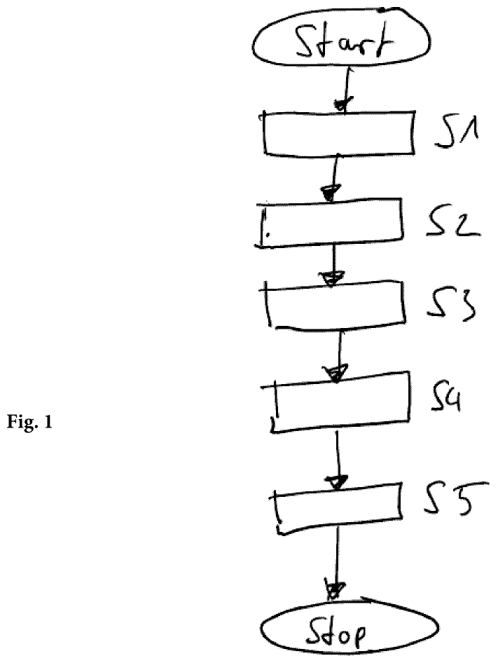

FIG. 1 illustrates, using a flow diagram, a method of assigning a specific type of vehicle to a user. This scenario can be part of assigning a leased vehicle to a user wherein, e.g., according to a target, a residual value of the vehicle is intended to be the maximum possible. Other targets can be set at a predetermined residual value after a predetermined lease period, i.e., useful life period wherein the residual value/potential use is largely determined by an ageing state then reached by the vehicle battery. This method also makes it possible determine the leasing rate for the user of each of the vehicles.

In step S1, a usage behavior of the user is provided for this purpose. This usage profile indicates a travel and charging behavior of the user, which can be obtained, e.g., by recording user trips using a current or former vehicle. Alternatively, the usage behavior can also be created by providing information about the user.

The usage behavior can be taken from the user's previous uses of vehicles and provide information about an estimated annual mileage, a ratio between the frequencies of fast charging and normal charging, an average charge stroke per charging operation, a driving style, in particular as an average and/or maximum acceleration during acceleration paths, an average battery temperature during operation of the vehicle, and the like.

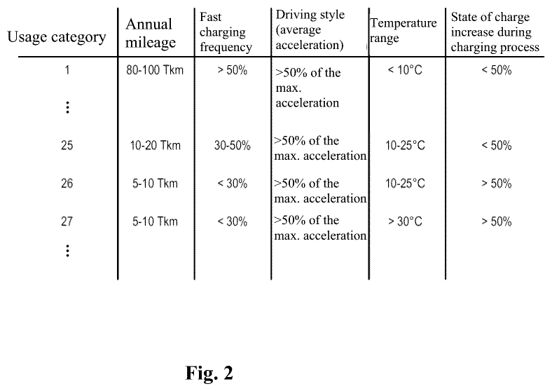

In step S1, the usage behavior is further categorized into a usage category. User categories can categorize various usage behaviors based on characteristic ranges of usage characteristics, which are shown by way of example in the table in FIG. 2. Various usage patterns are recognizable based on usage categories of usage that can be associated with a user. The usage categories differ by belonging to the above characteristics of the usage properties. The usage characteristics of correspond to aggregated usage parameters, which each indicate a parameter that characterizes a mode of operation of the technical device affecting a load on the device battery.

Each of the usage categories is associated with a usage parameter profile that indicates an artificial travel profile, i.e., a predicted usage parameter profile, for a predetermined usage duration. The predicted usage parameter profile is generally designed so that, in reality, it would lead to ageing of the vehicle battery that corresponds to the actual ageing of the vehicle battery when used by the user. For example, this predicted usage parameter profile can comprise a predicted speed profile at a high temporal resolution during the entire usage time period. The predicted usage parameter profile can also indicate charging times, the type of charging process, and a temperature profile during the period of use, etc.

Using a functional overall vehicle model, a powertrain model, and/or a battery model as a data-based, mathematically based, or physically based operational model, the usage parameter profile, i.e., the trajectories of travel movements, charging times, and idle times, e.g., in the form of a load profile, a charging current profile, and/or a speed profile and temperature profile, is then converted into a corresponding profile of the battery power and the battery temperature in step S2.

In so doing, a vehicle-level energy requirement is determined by means of the overall vehicle model, taking into account power fluxes in the vehicle, for example, auxiliary units such as an air conditioning system, a weight of the vehicle, a vehicle color, and/or rolling resistances.

By means of the vehicle-level energy requirement, the powertrain model, which comprises a thermal model, taking into account frictional torques and reduction of the reduction gear box for predetermined acceleration and deceleration times of a component protection with possible necessary power reduction and/or temperature control, appropriate expected torque requirements can be determined, which is represented by the underlying operational strategy stored on a model basis and can be used for simulation in the closed control loop.

By means of the torque requirements, with the aid of the battery model at the battery pack and system level, which comprises at least one thermal model, taking into account a nominal battery voltage, a battery conditioning, and/or an operational strategy of the battery, a resulting battery current profile from the usage variable profile, i.e. a power profile over time, and using forecasted ambient temperatures, e.g. from climate models, a resulting battery temperature profile can be determined.

By means of a battery performance model a corresponding battery voltage profile and state of charge profile is modeled from the battery current profile and the battery temperature profile in step S3. The change in the ageing state can be continuously taken into account in the battery performance model, in particular by parameter adjustment, in order to take into account the influence of the increasing ageing of the vehicle battery. The vehicle battery retains an operational variable profile until the end of the useful life period or lease duration.

Using a chronological integration-based ageing state model, a profile of the ageing state for the respective vehicle and in particular an ageing state for the end of the useful life period can be predicted based on the operational parameter profile during step S4. As a result, based on the predetermined user category, an ageing state is provided for each of the available vehicle types, which state indicates determination of a remaining ageing state at the end of the useful life period.

By means of a suitable rule-based selection criterion, e.g., selecting the type of vehicle causing the predetermined user category to have the least battery ageing over the overall lease period or, correspondingly, a minimum depreciation of the vehicle over the useful life period, wherein the depreciation of the vehicle depends on the ageing state at the end of the lease term, a selection of the type of vehicle can be made for the specific driver in step S6.

The respective vehicle is then provided to the user.

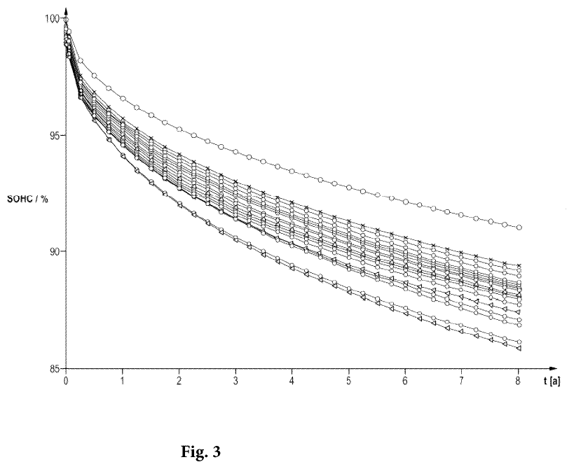

For example, FIG. 3 indicates possible ageing state profiles for a specific driver usage profile for various types of vehicles.

If the type of vehicle is assigned to a driver, then, while using the vehicle in real-world operation, it can be verified whether the actual ageing matches the simulated ageing previously performed for selecting the type of vehicle. In this case, a verification can first be performed in order to determine whether the assumed driver usage parameter profile deviates from the assigned usage category, e.g., based on the annual mileage and other usage parameters in the table shown in FIG. 2. If a classification is made into another use category, then a new simulation can be performed as previously described.

If the simulated operational parameter profiles, e.g., simulated battery temperatures, deviate from the real-world measured operational variables, an irregularity can be determined if a deviation of the actual ageing state from the previously simulated ageing state profile occurs. In addition, predictive maintenance can be planned and performed based on the irregularities previously determined.

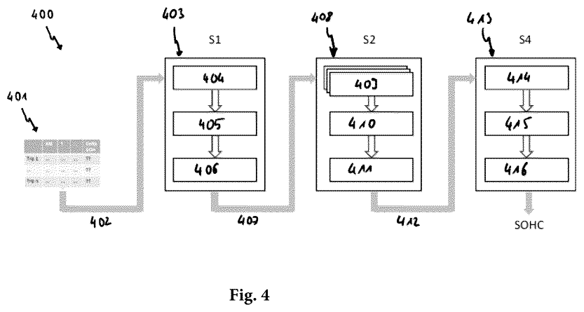

FIG. 4 shows a schematic illustration of a flowchart of an embodiment of a method 400 according to the invention. In a first step 403, S1, abstract load and operational variables 401 are captured, for example, possible usage categories for various behaviors of the driver. These can be provided, for example, via an application interface 402 by means of wired or wireless data connection.

The data regarding temperature profiles 404, charging cycles 405, and/or driving cycles 406 captured from the load and operational variables 401 are combined in step 403, S1 to serve as input parameters 407 for various vehicle models 409, 410, 411 in step 408, S2.

Because each vehicle potentially has a different powertrain and energy storage means, corresponding vehicle models, such as the overall vehicle model 409, the powertrain model 410, and/or the battery model 411, are present. In the illustrated embodiment, the powertrain model 410 and the battery model 411 each comprise a thermal model.

For example, a voltage level, a number of driven axles, and/or a reduction gear can be considered distinguishing features in relation to the powertrain.

For example, an output variable of the powertrain model 410 is a load requirement in relation to a high-voltage battery, typically expressed by power profiles or current profiles over time. Further, the load request can comprise a temperature load, specifically as an ambient temperature as a time series. Different cell chemistries can be used in the high-voltage battery, different electrolytes can be used, and/or the high-voltage batteries can have a differently sized capacities. Each of these high-voltage batteries therefore reacts differently to the input parameters and thus ages them differently. What is a stress factor for a certain high-voltage battery does not necessarily have to be a stress factor for another high-voltage battery.

The battery model 411 underlying the overall vehicle model 409 is used in order to map the load demanded by a powertrain over the associated load current of the high-voltage battery both in the discharging direction, i.e., in travel mode, and in the charging direction, i.e., during external charging or recuperation. Furthermore, load-free conditions, such as parking, can also be simulated in which a calendrical battery ageing can take effect.

The battery load current and the equally simulated battery temperature represent the input parameters 412 for the ageing simulation and long-term forecast for at least one usage scenario in step 413, S4.

In step 413, S4, the SOH algorithms are serviced with the variables load and charging current profile above temperature. The algorithms calculate the SOH profile for each vehicle model and determine the stress factors acting for this high-voltage battery under the same user behavior.

A cost function can be used in order to determine the residual value of the respective high-voltage battery for a predefined duration of the vehicle. The results of the battery simulation can be provided to a customer automatically, for example via the application interface. They involve vehicle-specific uncertainties and can describe tolerances and inaccuracies in the assumptions made by the underlying probabilistic models (hybrid model with Gaussian process).

The ageing simulation is embedded in the vehicle simulation, i.e., with a new ageing state, for example SOHC=0.9, the battery performance model is adjusted for age-relevant parameters and states in order to provide an age-dependent voltage and SOC response. In an advantageous embodiment, a usage model can also be integrated that changes usage behavior depending on age, for example, more frequent charging due to lower battery capacity.

In a further step, not shown, it is now checked whether the simulation assumptions are also fulfilled in real operation. Furthermore, via a battery model, it is checked whether the real ageing matches the simulated ageing of the hybrid data-based ageing state model.

If this is not the case, i.e., the assumptions for vehicle level simulation, such as vehicle parameters, mileage, and/or other usage parameters of the predicted load and operational variables, deviate too much from the measured variables, the hybrid data-based ageing state model is again executed with the updated assumptions in order to update the simulation results based on real field data.

If the temperatures measured in simulated variables, for example simulated temperatures, deviate too much from the actual measured variables, for example from temperatures sensed by module sensors, an irregularity is determined.

This happens precisely when a limit value compared to the vehicle simulation is exceeded. These irregularities refer to deviations from the simulated variables of the overall vehicle model with the powertrain model and battery model and include:
a real ageing of the SOHC or SOHR;
states in the powertrain, such as balancing, thermal management, and/or recuperation;
real battery loads, such as current, voltage, and temperature at the pack level, at the module level, and/or at the cell level.

After the hybrid data-based ageing state model and battery model have been executed and the simulation assumptions are validated, a further step is to schedule and perform predictive maintenance based on the irregularities, for example, a maintenance or inspection interval for temperature sensors.

This can now be done, because the driver-specific behavior is aligned with simulation assumptions. The goal of predictive maintenance is to maximize the availability of the vehicle while minimizing maintenance costs.

Thereby advantageously:
insurance products, such as warranty renewals, can be designed customized in a timely manner and assigned to the appropriate vehicles with the suitable powertrain for the customer;
available real data can be used in order to refine the simulation assumptions and thus predict the remaining value of the battery. Thus, a customer can be offered particularly favorable insurance of the battery in compliance with a proposed predictive maintenance.

In a further advantageous embodiment, the vehicle can be selected from the large number of possible vehicles by means of an optimization method, which best meets the user conditions and the target residual value depending on the agreed period of use.

With this a method is advantageously provided that enables a high-quality SOH prediction under different conditions, configurations and loads, and a leasing company can offer its customers a range of vehicles to suit their needs, taking into account their individual usage behavior.

In addition, the data as well as the stress factors recorded since commissioning serve as a transparent proof of performance for resale when the current leased vehicle is taken out of service. Thus, a fair assessment regarding residual value and performance of the battery can also take place.

1. A computer-implemented method for assigning a device type of a battery powered technical device having a device battery and belonging to a plurality of various device types to a user, said method comprising the following steps:
(S1) providing a usage behavior of the user;
assigning a usage category to the user's usage behavior;
determining a usage variable profile of at least one usage variable corresponding to the usage category, wherein the at least one usage parameter is indicative of a variable indicative of an operational mode of the technical device affecting a load on the device battery;
(S2) determining a predicted load variable profile using a data-based, mathematical, or physically motivated operational model;
(S4) simulating a predicted ageing state profile for the predicted load parameter profile for a predetermined amount of time for each type of device of a plurality of device types in order to determine a predicted ageing state at a predetermined end of useful life period; and
(S5) selecting a device type for the user depending on the predicted ageing state.

2. A method according to claim 1, wherein, in the case of an electrically driven vehicle as a technical device as an operational model, a powertrain model, and/or a battery model is provided.

3. The method according to claim 1, wherein the usage behavior of the user is continuously detected based on at least one usage variable and is derived from historical profiles of at least one usage variable, wherein the usage behavior is aggregated into usage characteristics, wherein the usage categories are determined by characteristics of the usage characteristics.

4. The method according to claim 3, wherein the usage characteristics comprise an average load during operation, a service duration relative to the calendar age, and a frequency of use, wherein in vehicles acting as technical devices, the usage characteristics comprise a predicted annual mileage, a number and type of charging cycles, a temperature range, and an average load range.

5. The method according to claim 1, wherein simulating the predicted ageing state profile for the predicted usage variable profile initially includes predicting at least one load variable profile for the device battery, which profile corresponds to at least one operational variable profile for the device battery, by means of a predetermined useful life period operational model for each device type, then predicting the ageing state profile by means of an ageing state model, wherein the ageing state model is based on a differential equation system which determines the ageing state by means of a chronological integration method.

6. The method according to claim 5, wherein at least one additional of the at least one operational variables is determined by means of a battery performance model dependent on the at least one load variable profile, wherein, for the simulation, the model parameters of the battery performance model are adjusted with respect to the respective predicted ageing state.

7. The method according to claim 1, wherein selecting a device type for the user is performed at the end of the predetermined useful life period, depending on the predicted state of ageing, so that a remaining potential use of the device battery is at a maximum.

8. A use of a method according to claim 1 for electrically driven vehicles for a simulation of an operational strategy on power and thermal behavior in the closed control loop, wherein an overall vehicle model, a powertrain model, and/or a battery model is provided as an operational model in order to predict a state of an energy converter or electrochemical energy storage means of the electrically driven vehicle.

9. An apparatus for performing a method according to claim 1.

10. A non-transitory, computer-readable storage medium comprising instructions that, when executed by at least one data processing device, cause the latter to assign a device type of a battery powered technical device having a device battery and belonging to a plurality of various device types to a user, by:
providing a usage behavior of the user;
assigning a usage category to the user's usage behavior;
determining a usage variable profile of at least one usage variable corresponding to the usage category, wherein the at least one usage parameter is indicative of a variable indicative of an operational mode of the technical device affecting a load on the device battery;
determining a predicted load variable profile using a data-based, mathematical, or physically motivated operational model;
simulating a predicted ageing state profile for the predicted load parameter profile for a predetermined amount of time for each type of device of a plurality of device types in order to determine a predicted ageing state at a predetermined end of useful life period; and
selecting a device type for the user depending on the predicted ageing state.
